(19) United States
(12) Patent Application Publication
(10) Pub. No.: US 2025/0014877 A1
(43) Pub. Date: Jan. 9, 2025

(54) PLASMA PROCESSING APPARATUS AND PLASMA PROCESSING METHOD

(71) Applicant: Panasonic Intellectual Property Management Co., Ltd., Osaka (JP)

(72) Inventors: Hisao NAGAI, Osaka (JP); Shogo OKITA, Hyogo (JP); Toshiyuki TAKASAKI, Osaka (JP); Seiya NAGANO, Osaka (JP); Naoaki TAKEDA, Osaka (JP); Takahiro MIYAI, Osaka (JP)

(21) Appl. No.: 18/761,458

(22) Filed: Jul. 2, 2024

(30) Foreign Application Priority Data
Jul. 7, 2023 (JP) 2023-112310

(51) Int. Cl. H01J 37/32

(52) U.S. Cl. CPC H01J 37/3299; H01J 37/3211; H01J 37/32183; H01J 37/32449; H01J 37/32926; H01J 37/32981; H01J 2237/334

(57) ABSTRACT

A plasma processing apparatus including a chamber, a placement unit which is disposed in the chamber and on which a substrate is to be placed, a plasma generation unit configured to generate a plasma within the chamber, a gas supply unit configured to supply a raw material gas of the plasma into the chamber, a measurement unit configured to measure and output a distribution information regarding a plasma distribution in the chamber, a control unit configured to control the plasma generation unit and the gas supply unit so as to repeat a unit processing on the substrate, a memory unit configured to store process conditions including conditions for the unit processing, and a modification unit configured to modify the process conditions. The measurement unit measures the distribution information (N) in the unit processing (N) at an Nth time, where N is an integer. When the distribution information (N) satisfies a predetermined condition, the modification unit modifies the process conditions in the unit processing (M) at an Mth time, where M is any integer equal to or greater than (N+1).

### CROSS REFERENCE TO RELATED APPLICATION

The present disclosure is based on and claims priority under 35 U.S.C. § 119 with respect to the Japanese Patent Application No. 2023-112310 filed on Jul. 7, 2023, of which entire content is incorporated herein by reference into the present application.

### TECHNICAL FIELD

The present disclosure relates to a plasma processing apparatus and a plasma processing method.

### BACKGROUND

Patent Literature 1 (JP2018-137405A) proposes “a method for manufacturing an element chip, the method comprising: a preparation step of preparing a substrate having a first principal surface and a second principal surface, and including a first layer, a second layer which is a semiconductor layer formed on the first layer on the side facing the second principal surface, a plurality of element regions, and a plurality of streets defining the element regions; a placement step of placing the substrate on a stage installed in a chamber of a plasma processing apparatus, with the second principal surface facing to the stage; and a plasma dicing step of exposing the substrate to a plasma generated within the chamber by application of a high-frequency power to an electrode included in the plasma processing apparatus, to divide the substrate into a plurality of element chips having the element regions, wherein the plasma dicing step includes a first etching of repeating a cycle including an etching step of forming grooves corresponding to the streets in the second layer, and a deposition step of depositing a protective film on inner walls of the grooves, to form first scallops at a first pitch PT1 along the inner walls of the grooves, and a second etching of forming second scallops at a second pitch PT2 after the first etching, the PT1 and the PT2 satisfying PT1<PT2.”

### SUMMARY

In order to allow etching to proceed uniformly within the processing region of the substrate surface, it is required to make the plasma distribution uniform on the substrate surface.

One aspect of the present disclosure relates to a plasma processing apparatus, including: a chamber; a placement unit which is disposed in the chamber and on which a substrate is to be placed; a plasma generation unit configured to generate a plasma within the chamber; a gas supply unit configured to supply a raw material gas of the plasma into the chamber; a measurement unit configured to measure and output a distribution information regarding a plasma distribution in the chamber; a control unit configured to control the plasma generation unit and the gas supply unit so as to repeat a unit processing on the substrate; a memory unit configured to store process conditions including conditions for the unit processing; and a modification unit configured to modify the process conditions, wherein the measurement unit measures the distribution information (N) in the unit processing (N) at an Nth time, where Nis an integer, and when the distribution information (N) satisfies a predetermined condition, the modification unit modifies the process conditions in the unit processing (M) at an Mth time, where M is any integer equal to or greater than (N+1).

Another aspect of the present disclosure relates to a plasma processing method in which a unit processing with respect to a substrate is repeated using a plasma generated by application of a high-frequency power to a raw material gas supplied from a gas supply unit, the method including: a measurement step of measuring and outputting a distribution information regarding a plasma distribution in the unit processing (N) at an Nth time, where N is an integer; and a modification step of, when the distribution information measured in the measurement step satisfies a predetermined condition, modifying the process conditions in the unit processing (M) at an Mth time, where M is any integer equal to or greater than (N+1).

According to the present disclosure, it is possible to make the plasma distribution on the substrate surface uniform during processing of the substrate.

While the novel features of the invention are set forth particularly in the appended claims, the invention, both as to organization and content, will be better understood and appreciated, along with other objects and features thereof, from the following detailed description taken in conjunction with the drawings.

### BRIEF DESCRIPTION OF THE DRAWINGS

FIG. 1 is a schematic cross-sectional view of a plasma processing apparatus according to Embodiment 1.

FIG. 2 is a schematic plan view of a cover according to Embodiment 1.

FIG. 3 is a flow diagram of a plasma processing method according to Embodiment 1.

FIG. 4 is a conceptual diagram of an example of process conditions.

FIG. 5 is a flow diagram of the operation of a measurement unit according to Embodiment 1.

FIG. 6 is a flow diagram of the operation of a modification unit according to Embodiment 1.

FIG. 7 is a conceptual diagram of a modification example of the process conditions.

FIG. 8 is a conceptual diagram of another modification example of the process conditions.

FIG. 9 is a conceptual diagram of yet another modification example of the process conditions.

### DETAILED DESCRIPTION

Embodiments of the plasma processing apparatus and the plasma processing method according to the present disclosure will be described below by way of examples. The present disclosure, however, is not limited to the examples described below. In the following description, specific numerical values and materials are exemplified in some cases, but other numerical values and other materials may be adopted as long as the effects of the present disclosure can be obtained.

For the components other than those characteristic of the present disclosure, known components of plasma processing apparatuses and plasma processing methods may be adopted. In the present specification, when referring to “a range of a numerical value A to a numerical value B,” the range includes the numerical value A and the numerical value B. In the following description, when the lower and upper limits of numerical values regarding specific physical properties, conditions, etc. are mentioned as examples, any one of the mentioned lower limits and any one of the mentioned upper limits can be combined in any combination as long as the lower limit is not equal to or more than the upper limit.

The present disclosure encompasses a combination of matters recited in any two or more claims selected from plural claims in the appended claims. In other words, as long as no technical contradiction arises, matters recited in any two or more claims selected from plural claims in the appended claims can be combined.

### (Plasma Processing Apparatus)

A plasma processing apparatus according to the present disclosure is an apparatus for plasma processing a substrate. The plasma processing apparatus encompasses, for example, a plasma etching apparatus, a plasma dicer, a plasma ashing apparatus, a plasma CVD apparatus, and the like.

The substrate may be of any type and form. The substrate may also be rephrased as an “object to be processed.” The substrate can be, for example, a substrate which includes a semiconductor layer having a first principal surface and a second principal surface, and includes a plurality of element regions and a plurality of streets defining the element regions. The element regions include, for example, a semiconductor layer and a wiring layer. By etching the street regions, element chips each having a semiconductor layer and a wiring layer can be obtained. The substrate may be supported on a carrier and placed on a stage. The carrier may be, for example, a resin sheet with its outer peripheral part held by a frame.

The plasma processing apparatus includes a chamber, a placement unit (stage), a plasma generation unit, a gas supply unit, a measurement unit for measuring the state of plasma, a modification unit for modifying process conditions, a control unit for performing a predetermined control, a memory unit, and the like.

Processing of the substrate is performed within the chamber. The upper part of the chamber may have an opening directed upward. The opening is closed with a dielectric member. The chamber may be formed in a hollow cylindrical shape. Closing the opening with the dielectric member forms a first space within the chamber. The first space is a space in which the placement unit is disposed. The dielectric member may be formed in a plate shape having a horizontally extending region. The dielectric member may be constituted of, for example, ceramics, such as quartz, alumina, and aluminum nitride.

The dielectric member may be provided at its center with a through-hole passing vertically through the dielectric member. The through-hole may be communicated with a second space surrounded by a protruding portion extending upward above the dielectric member. The first space and the second space communicate with each other via the through-hole. Such a second space allows for easy control of the distribution of the plasma generated in the first space. The lower end of the protrudin portion is fitted into the through-hole. The protruding portion may be formed in a cylindrical shape extending vertically. The protruding portion may be constituted of a dielectric, or other materials.

The protruding portion may have a dielectric window provided at its upper end (top). The dielectric window is transparent to light and may be constituted of quartz, for example. The dielectric window may be used in measuring the state of plasma in the first space. The dielectric window is positioned above the dielectric member, that is, at a position away from the first space. Therefore, reaction products generated during processing of the substrate in the first space hardly adhere to the dielectric window.

The placement unit is disposed in the chamber. The placement unit is an element on which a substrate is to be placed. The placement unit may have a horizontal placement surface for placing a substrate thereon. The placement unit may have a flow path for a coolant for cooling the substrate to flow during plasma processing. The placement unit may have an electrostatic chuck system for chucking a substrate. The placement unit may have a lower electrode to which a high-frequency power is to be applied.

The plasma generation unit is an equipment that generates a plasma within the chamber. The plasma generation unit includes at least one induction coil, a power source that supplies electric power to the induction coil, a distributor that, when two or more induction coils are provided, distributes the power between the induction coils, a matcher, and the like.

The gas supply unit is an equipment that supplies a raw material gas of the plasma into the chamber. The gas supply unit includes, for example, a gas flow path, a gas introduction part that guides the raw material gas to the gas flow path, a gas release part that releases the raw material gas into the chamber, and the like.

The measurement unit is an equipment that measures and outputs a distribution information regarding the plasma distribution in the chamber. The measurement unit includes a predetermined sensor, a processor that processes measurement data, an output unit, and the like.

The control unit controls the plasma generation unit and the gas supply unit so as to repeat a unit processing with respect to the substrate. The control unit may be a central processing unit (CPU). The control unit may be configured to control the measurement unit and the modification unit.

The memory unit stores process conditions including conditions for the unit processing. The memory unit may store a data indicating the correlation between an output of the measurement unit and a corrected process condition to be selected by the modification unit according to the output. The memory unit may store a function that, based on the above output as an input, outputs the corrected process condition. The memory unit may store a program to be executed by the control unit.

Here, the plasma processing apparatus includes a modification unit that modifies the process conditions, when the distribution information regarding the plasma distribution satisfies a predetermined condition. The modification unit modifies the process conditions according to the output of the measurement unit, so that the plasma distribution on the substrate surface is made uniform during processing of the substrate. This reduces the variations in process conditions within the processing region of the substrate. The modification unit may be rephrased, depending on the situation, as a correction unit that corrects the process conditions during processing of the substrate. When the distribution information regarding the plasma distribution does not satisfy a predetermined condition, and there is no need to modify the process conditions, the modification unit does not modify the process conditions.

When satisfying a predetermined condition means when a distribution information is outputted which indicates that the plasma distribution is not sufficiently uniform. The modification unit may include a determination unit that determines whether or not satisfying a predetermined condition, that is, whether or not to modify the process conditions.

Specifically, the measurement unit measures and outputs the distribution information (N) regarding the plasma distribution in the unit processing (N) at an Nth time, where N is an integer. The modification unit modifies (corrects) the process conditions in the unit processing (M) at an Mth time, where M is an integer equal to or greater than (N+1), based on the outputted distribution information (N). Since the unit processing is repeated a plurality of times, the substrate is processed under the corrected process conditions from some point during the processing. Performing the above correction at an early stage of a plurality of times of unit processing can significantly suppress the variations in the state of processing of the substrate within the processing region. The above correction is performed at least once, but may be performed a plurality of times. For example, when the total number of times of the unit processing is denoted by L, the correction can be performed (L−1) times at maximum.

When the processing of the substrate is singulation or deep etching of the substrate, the unit processing can be a unit processing in the Bosch process. The unit processing includes, for example, a deposition step of depositing a protective film on the surface of the substrate, a protective film removal step of removing the protective film, to expose part of the substrate, and a substrate etching step of etching the exposed part of the substrate. Repeating such a unit processing can form grooves on the substrate, or singulate the substrate. When the substrate includes a plurality of element regions and a plurality of street regions defining the element regions, grooves are formed along the street regions, or the street regions are removed, so that the substrate is singulated.

When the unit processing including a deposition step, a protective film removal step, and a substrate etching step is repeated, the measurement unit preferably measures and outputs the distribution information (N) regarding the plasma distribution in the substrate etching step, in the unit processing (N) at an Nth time, where Nis an integer. In this case, the modification unit can appropriately modify the conditions for the substrate etching step, based on the distribution information (N), in any unit processing (M) performed after the Nth unit processing.

The modification unit may modify, in addition to the conditions for the substrate etching step in the unit processing (M), the conditions for the protective film removal step in the unit processing (M). The conditions for the protective film removal step may be modified to be similar to those for the substrate etching step. Since the protective film removing step and the substrate etching step are continuous, setting the conditions for the protective film removing step and those for the substrate etching step as close as possible can make the plasma discharge state in the substrate etching step more stabilized. For example, the conditions for the protective film removal step and those for the substrate etching step may be set the same, except for the high-frequency power (bias power) applied to the placement unit (or lower electrode) and the application time.

The measurement unit may include a first sensor that measures light emission from the center area of the plasma generated within the chamber, and a second sensor that measures light emission from the circumferential area of the plasma generated within the chamber. In this case, a distribution information can be outputted, based on a first emission intensity measured by the first sensor and a second emission intensity measured by the second sensor. The first emission intensity reflects the plasma intensity in the region above the center area of the substrate, and the second emission intensity reflects the plasma intensity in the region above the circumferential area of the substrate. The modification unit modifies (corrects) the process conditions in the Mth unit processing (M) so as to make the plasma intensities in the regions above the center area and the circumferential area of the substrate closer to each other. Further outputting a distribution information for feedback after the process condition modification can further enhance the uniformity of the plasma distribution on the substrate surface, during processing of the substrate.

The first sensor and the second sensor may be each an optical sensor capable of acquiring the spectral intensity of light emitted from plasma, and the types of the first and second sensors are not particularly limited.

When the dielectric member has at its center a protruding portion having a dielectric window (first dielectric window) at its upper end (top), the first sensor may be disposed above the first dielectric window. The first sensor measures a first emission intensity from the center area of the plasma in the first space, through the first dielectric window.

The height of the protruding portion may be greater than the diameter of the protruding portion. According to this configuration, since the second space is long in the vertical direction, reaction products generated in the first space are hard to reach the first dielectric window. Therefore, the first dielectric window is further less likely to be dirty or contaminated, and the measurement accuracy of the first emission intensity of plasma can be further improved. The first dielectric window may be disposed at a position higher than the uppermost top of the induction coil. For example, the first dielectric window may be disposed at a position where it is not shielded by the lid covering the induction coil. With this configuration, the state of plasma can be measured with no restriction of space.

When the chamber has on its sidewall a second dielectric window, the second sensor may be provided outside the second dielectric window. The second sensor is disposed in proximity to the second dielectric window. The second sensor measures a second emission intensity from the circumferential area of the plasma in the first space, through the second dielectric window.

The second sensor may measure an emission intensity of plasma in the vicinity of the second dielectric window, as the second emission intensity. In the case of measuring plasma in the vicinity of the second sensor, a lens with a short focal length can be used.

The second sensor may include: a convex lens that collects the light emitted from plasma within the chamber; a light emission detector that detects the light emitted from plasma through the convex lens; a first driving unit that moves the light emission detector, along the optical axis passing through the plasma, the second dielectric window, and the convex lens; and a second driving unit that moves the convex lens and the light emission detector, perpendicular to the optical axis, along a plane parallel to the substrate surface. The light emitted from plasma passes through the second dielectric window, and is collected by the convex lens, to be focused outside the chamber.

Using the first driving unit and the second driving unit, the focal point of the convex lens can be moved within the region where plasma is generated. Moving the focal point can extract the light emitted from plasma at any position on the substrate. A shutter may be installed so as to close the center of the convex lens. With the shutter, which blocks the light (zero-order light) passing through the center of the convex lens, only the light refracted and focused by the convex lens can be collected. Therefore, only the light emission from plasma at a desired position can be highly accurately detected.

The raw material gas may include, for example, a fluorine source and an inert gas. The fluorine source may be a compound containing a fluorine atom. The compound containing a fluorine atom may be sulfur hexafluoride (SF₆), may be nitrogen trifluoride (NF₃), and may be fluorocarbon. These compounds containing a fluorine atom generate fluorine (F) in the plasma. The inert gas may be, for example, argon. When the raw material gas contains a fluorine source and argon, the emission intensity (spectral intensity) of fluorine generated from the fluorine source and the emission intensity (spectral intensity) of the argon can be measured as the first emission intensity and the second emission intensity. As the emission intensity of the fluorine, for example, a peak intensity at or around a wavelength of 703.7 nm in the emission spectrum of plasma can be used. As the emission intensity of the argon, for example, a peak intensity at or around a wavelength of 750.4 nm in the emission spectrum of plasma can be used.

From the first emission intensity, a ratio (first intensity ratio) of the emission intensity attributed to the fluorine generated from the fluorine source in the center area of the plasma to the emission intensity attributed to the argon in the center area of the plasma can be calculated.

From the second emission intensity, a ratio (second intensity ratio) of the emission intensity attributed to the fluorine generated from the fluorine source in the circumferential area of the plasma to the emission intensity attributed to the argon in the circumferential area of the plasma can be calculated.

The measurement unit may output the first intensity ratio and the second intensity ratio, as the distribution information. When the distribution information includes the first intensity ratio and the second intensity ratio, the modification unit may modify the process conditions, based on the distribution information (the first intensity ratio and the second intensity ratio), and on a data acquired in advance. The data acquired in advance may be a data indicating the interdependency between the ratio of an emission intensity attributed to the fluorine and an emission intensity attributed to the argon (F/Ar ratio), and the etching rate of the substrate.

On the inner surfaces of the first and second dielectric windows, reaction products adhere. The measurement values of the emission intensity of fluorine and the emission intensity of argon, therefore, change over time. The F/Ar ratio, however, is not influenced by contamination on the inner surfaces of the first and second dielectric windows. Therefore, changes in the emission intensity of fluorine in the plasma can be purely measured.

The data indicating the interdependency between the F/Ar ratio and the etching rate of the substrate is preferably measured during the stable period of the plasma, rather than during the unstable period from when a plasma is ignited until the plasma is stabilized. For example, the average value and the standard deviation of the first emission intensity and the second emission intensity (first intensity ratio and second intensity ratio) during the stable period, and the etching rate of the substrate are measured. The etching rate can be calculated by, for example, measuring the etched amount of the substrate using a film thickness meter or the like, and dividing the etched amount by the time taken for etching. Several tens to several hundreds of substrates may be subjected to etching, to calculate the average value and the standard deviation of the F/Ar ratio and the etching rate.

It is desirable to similarly calculate the average value and the standard deviation of device parameters other than the parameters regarding emission intensity. The device parameters may be, for example, those of a high-frequency power source of the plasma generation unit, a distributor, and a matcher (e.g., capacitance of variable capacitor), the gas flow rate through the gas introduction part in the gas supply unit, and the like. By doing this, data showing the interdependency between the F/Ar ratio and the device parameters can be obtained.

The plasma generation unit may include a first coil (inner coil) for generating a plasma in the center area within the chamber, a second coil (outer coil) for generating a plasma in the circumferential area within the chamber, and a power supply unit that supplies a high-frequency power to each of the first coil and the second coil. In this case, the process conditions may include a first setting value regarding an electric power supplied from the power supply unit to each of the first coil and the second coil (e.g., the ratio between the power supplied to the first coil and the power supplied to the second coil). The modification unit may modify the first setting value in the Mth unit processing (M), based on the distribution information. By doing this, the power supplied from the power supply unit to the first coil and the second coil can be corrected, leading to improved uniformity of plasma.

The first coil is disposed above the dielectric member (outside the first space), in the center area of the dielectric member. The first coil is arranged, for example, in an annular region excluding the protruding portion extending upward above the dielectric member so as to face the first space. The magnetic field generated by the first coil mainly acts, via the dielectric member, on the raw material gas in the center area of the first space.

The second coil is disposed outside the first coil, so as not to vertically overlap with the first coil. The second coil is arranged, for example, above the dielectric member and circumferentially outside the annular region where the first coil is arranged, so as to face the first space. According to this configuration, in which the power supplied to the first and second coils is adjusted, the distribution of plasma on the substrate can be controlled with high flexibility, and the uniformity of the distribution of plasma on the substrate surface can be enhanced.

The power supply unit may include one high-frequency power source, a matcher connected to the output end of the high-frequency power source, and a distributor that is connected to the matcher on the opposite side to the high-frequency power source and distributes the total electric power supplied from the high-frequency power source between the first coil and the second coil at a predetermined distribution ratio. The control unit is preferably configured to control the distribution ratio of the distributor. In this case, the first setting value regarding the electric power may include the distribution ratio that determines the ratio between the power supplied to the first coil and the power supplied to the second coil. That is, the modification unit may modify the distribution ratio in the Mth unit processing (M), based on the information on plasma distribution. When the first coil and the second coil are connected in parallel to one high-frequency power source via a matcher, the device configuration is simpler than when the first coil and the second coil are connected to respective high-frequency power sources. Furthermore, only one matcher suffices, and the stability of the plasma after the process condition modification also improves. The first setting value may further include the total electric power outputted from the high-frequency power source.

In modifying the process conditions, only the distribution ratio may be modified, with no modification to the total electric power outputted from one high-frequency power source. That is, the modification unit may modify the distribution ratio in the Mth unit processing (M), based on the information on plasma distribution, without modifying the total electric power. When only the distribution ratio is used to adjust the distribution state of plasma, the control can be performed with high responsiveness, as compared to when each of the first and second coils is provided with a power supply and a matcher.

The gas supply unit may include a first supply unit that supplies the raw material gas into the center area of the chamber, and a second supply unit that supplies the raw material gas into the circumferential area of the chamber. In this case, the process conditions may include a second setting value regarding the raw material gas supplied into the chamber from each of the first supply unit and the second supply unit (e.g., the ratio between a flow rate of the gas supplied from the first supply unit and a flow rate of the gas supplied form the second supply unit). The modification unit may modify the second setting value in the Mth unit processing (M), based on the information on plasma distribution. By doing this, the ratio between the flow rates of the raw material gas supplied into the chamber from the first supply unit and the second supply unit is corrected, leading to improved uniformity of plasma.

The first supply unit may have a first gas release part in a region adjacent to the dielectric member and facing the first coil. The second supply unit may include a second gas release part in a region adjacent to the dielectric member and facing the second coil. The raw material gas is supplied from the first gas release part to the vicinity of the first coil and from the second gas release part to the vicinity of the second coil. This allows a plasma to be generated with high efficiency.

### (Plasma Processing Method)

A plasma processing method according to the present disclosure is a method of processing a substrate using the above-described plasma processing apparatus, in which a unit processing with respect to a substrate is repeated using a plasma generated by application of a high-frequency power to a raw material gas supplied from a gas supply unit. The plasma processing method includes a measurement step of measuring and outputting a distribution information regarding a plasma distribution in the unit processing (N) at an Nth time, where N is an integer, and a modification step of, when the distribution information measured in the measurement step satisfies a predetermined condition, modifying the process conditions in the unit processing (M) at an Mth time, where M is any integer equal to or greater than (N+1).

The unit processing may include, as described above, a deposition step of depositing a protective film on the surface of the substrate, a protective film removal step of removing part of the protective film, to expose part of the substrate, and a substrate etching step of etching the exposed part of the substrate. In this case, the modification step may be a step of modifying at least the conditions for the substrate etching step in the unit processing (M), based on the distribution information (N). In the modification step, the conditions for the protective film removing step in the unit processing (M) may also be modified.

The measurement step may include a first measurement step of measuring light emission from the center area of the plasma generated within the chamber, with a first sensor, and a second measurement step of measuring light emission from the circumferential area of the plasma generated within the chamber, with a second sensor. In this case, a distribution information may be outputted, based on a first emission intensity measured by the first sensor and a second emission intensity measured by the second sensor.

The raw material gas may include a fluorine source and argon. In this case, in the measurement step, a first intensity ratio and a second intensity ratio may be outputted as the distribution information. The first intensity ratio is the ratio of an emission intensity attributed to fluorine generated from the fluorine source to an emission intensity attributed to the argon, which are measured by the first sensor. The second intensity ratio is the ratio of an emission intensity attributed to the fluorine to the emission intensity attributed to the argon, which are measured by the second sensor. In the modification step, the process conditions may be modified, based on the distribution information (first intensity ratio and second intensity ratio) and a data acquired in advance. The data acquired in advance may include an interdependency data between the ratio of an emission intensity attributed to the fluorine to an emission intensity attributed to the argon and the etching rate of the substrate.

The plasma can be generated by a plasma generation unit including a first coil for generating a plasma in the center area within the chamber, a second coil for generating a plasma in the circumferential area within the chamber, and a power supply unit for supplying a high-frequency power to each of the first coil and the second coil. In this case, the process conditions can include a first setting value regarding the power supplied from the power supply unit to each of the first coil and the second coil. In the modification step, the first setting value in the Mth unit processing (M) may be modified, based on the distribution information (first intensity ratio and second intensity ratio).

The power supply unit can include one high-frequency power source, a matcher connected to the output end of the high-frequency power source, and a distributor that is connected to the matcher on the opposite side to the high-frequency power source and distributes the total electric power supplied from the high-frequency power source between the first coil and the second coil at a predetermined distribution ratio. In this case, the first setting value can include the distribution ratio. In the modification step, the distribution ratio in the Mth unit processing (M) may be modified, based on the distribution information (first intensity ratio and second intensity ratio). In the modification step, only the distribution ratio may be modified, with no modification to the total electric power.

The gas supply unit can include a first supply unit that supplies the raw material gas into the center area of the chamber, and a second supply unit that supplies the raw material gas into the circumferential area of the chamber. In this case, the process conditions may include a second setting value regarding the raw material gas supplied into the chamber from each of the first supply unit and the second supply unit. In the modification step, the second setting value in the Mth unit processing (M) may be modified, based on the distribution information (first intensity ratio and second intensity ratio).

In the following, examples of the plasma processing apparatus and method according to the present disclosure will be specifically described with reference to the drawings. The components and processes as described above can be applied to the components and processes of the below-described examples of the plasma processing apparatus and method. The components and processes of the below-described examples of the plasma processing apparatus and method can be modified based on the description above. The matters as described below may be applied to the above embodiments. Of the components and processes of the below-described examples of the plasma processing apparatus and method, the components and processes which are not essential to the plasma processing apparatus and method according to the present disclosure may be omitted. The figures below are schematic and not intended to accurately reflect the shape and the number of the actual members.

### Embodiment 1

Embodiment 1 of the present disclosure will be described. A plasma processing apparatus 10 of the present embodiment is for plasma processing a substrate (e.g., a semiconductor substrate). The plasma processing apparatus 10 of the present embodiment is a plasma dicer, but is not limited thereto.

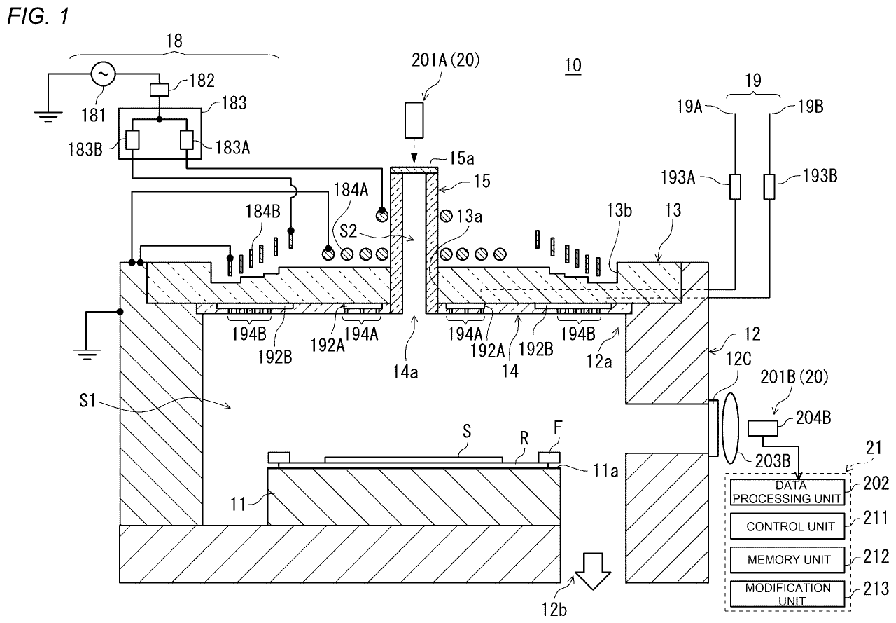

As illustrated in FIG. 1, the plasma processing apparatus 10 includes a chamber 12, a placement unit (stage) 11 disposed in the chamber 12 and on which a substrate S is placed, a plasma generation unit 18 that generates a plasma within the chamber, a gas supply unit 19 that supplies a raw material gas of the plasma into the chamber, a measurement unit 20 that measures and outputs a distribution information regarding the plasma distribution in the chamber, and a computer 21 including a control unit 211, a memory unit 212, and a modification unit 213.

The control unit 211 controls the plasma generation unit and the gas supply unit so as to repeat a unit processing with respect to the substrate. The memory unit 212 stores process conditions including conditions for the unit processing. The modification unit 213 modifies the process conditions when the distribution information satisfies a predetermined condition. The operations of the control unit 211 and the modification unit 213 may be executed by a central processing unit (CPU) included in the computer 21. The memory unit 212 may store programs to be executed by the control unit 211 and the modification unit 213.

A substrate S is supported on a resin sheet R with its outer peripheral part held by a frame F, and placed on the placement unit 11. The placement unit 11 has a horizontal mounting surface 11a for placing a substrate thereon. The placement unit 11 may have a flow path for a coolant for cooling the substrate to flow during plasma processing. The placement unit 11 may have an electrostatic chuck system for chucking a substrate. The placement unit 11 may have a lower electrode to which a high-frequency power is to be applied.

The chamber 12 has a hollow cylindrical shape, and has at its top an opening 12a which is open upward. The opening 12a is closed with a dielectric member 13. Closing the opening with the dielectric member 13 forms a first space S1 within the chamber 12. The first space S1 is a space in which the placement unit 11 is disposed. The dielectric member 13 is formed in a plate shape having a horizontally extending region, and has on its upper surface a recessed portion 13b. The chamber 12 has an exhaust port 12b for exhausting the raw material gas used for plasma processing. To the exhaust port 12b, an exhaust device is connected. The chamber 12 is constituted of a conductive member (e.g., metal). The dielectric member 13 is constituted of, for example, quartz.

The dielectric member 13 is provided at its center with a through-hole passing vertically through the dielectric member 13, and the through-hole is communicated with a second space S2 surrounded by a cylindrical protruding portion 15 extending upward above the dielectric member 13. The second space S2 allows for easy control of the distribution of the plasma generated in the first space S1. The protruding portion 15 is provided at its upper end (top) with a first dielectric window 15a. The protruding portion 15 is constituted of, for example, aluminum nitride.

The plasma generation unit 18 includes a high-frequency power source 181, a matcher 182, a distributor 183, a first coil 184A, and a second coil 184B. The high-frequency power (e.g., AC power of 3 to 30 MHz) outputted from the high-frequency power source 181 is distributed at a predetermined distribution ratio by the distributor 183 via the matcher 182 equipped with a variable capacitor, and connected to one ends of the first coil 184A and the second coil 184B. The other ends of the first coil 184A and the second coil 184B are grounded via the chamber 12 which is electrically conductive.

The distributor 183 has a first distribution circuit 183A that distributes part of high-frequency power outputted from the high-frequency power source 181 to the first coil 184A, and a second distribution circuit 183B that distributes part of the high-frequency power to the second coil 184B. The first distribution circuit 183A includes, for example, a first variable capacitor and an inductor that are connected in parallel with each other, and a capacitor that is connected in series on the downstream of the both. The second distribution circuit 183B includes, for example, a second variable capacitor. The first distribution circuit 183A and the second distribution circuit 183B are connected in parallel to each other.

The distribution ratio of the high-frequency power between the first coil 184A and the second coil 184B is controlled by the control unit 211. The control unit 211 modifies the distribution ratio through controlling the distributor 183, for example, through adjusting the capacitance value of each variable capacitor included in the distributor 183. Specifically, when the distribution information outputted by the measurement unit is to request to modify the process conditions, the first setting value regarding the distribution ratio is modified by the modification unit, and the distribution ratio is modified by the control unit 211 according to the modified first setting value. At this time, the distribution ratio may be modified, with no modification to the total electric power outputted by the high-frequency power source 181.

The matcher 182 is configured to match the impedance (input impedance) of the high-frequency power source 181 and the impedance (load impedance) on the downstream of the matcher 182. The matcher 182 may have at least one variable capacitor, so that impedance matching may be performed by changing the capacitance value of the at least one variable capacitor. The matcher 182 may be an auto-matching unit with which impedance matching is automatically executable.

The first coil 184A is disposed, above the dielectric member 13 (outside the first space), in the center area of the dielectric member 13. The first coil 184A is arranged so as to face the first space, for example, in an annular region excluding the protruding portion extending upward above the dielectric member 13. The magnetic field generated by the first coil 184A mainly acts, via the dielectric member, on the raw material gas in the center area of the first space.

The second coil 184B is disposed so as to face the first space, outside the first coil 184A so as not vertically overlap with the first coil 184A. The second coil 184B includes one or more conductors each extending spirally in the circumferential direction. Part of the second coil 184B on the outer peripheral side is disposed inside the recessed portion 13b formed in the dielectric member 13.

The gas supply unit 19 can include a first supply unit 19A that supplies the raw material gas into the center area of the chamber, and a second supply unit 19B that supplies the raw material gas into the circumferential area of the chamber. The first supply unit 19A includes a first gas flow path 192A, a first flow controller 193A, and a first gas release part 194A. The second supply unit 19B includes a second gas flow path 192B, a second flow controller 193B, and a second gas release part 194B. The first supply unit 19A is connected to a first gas storage unit, the second supply unit 19B is connected to a second gas storage unit, and the raw material gas is stored in each gas storage unit. The raw material gas stored in the first gas storage unit passes through the first gas flow path 192A while its flow rate is under control by the first flow rate controller 193A, and is released into the chamber 12 from the first gas release part 194A. The raw material gas stored in the second gas storage unit passes through the second gas flow path 192B while its flow rate is under control by the second flow rate controller 193B, and is released into the chamber 12 from the second gas release part 194B.

The lower surface of the dielectric member 13 is covered with a cover 14. The cover 14 is provided at its center with a second through-hole 14a so as to overlap with the through-hole (first through-hole 13a) of the dielectric member 13. The cover 14 is constituted of, for example, aluminum nitride. The cover 14 has the first gas flow path 192A that supplies the raw material gas into a region facing the first coil 184A in the first space S1, and the second gas flow path 192B that supplies the raw material gas into a region facing the second coil 184B in the first space S1. The first gas flow path 192A and the second gas flow path 192B are composed of grooves or cavities formed on the upper surface of the cover 14. Thus, the first gas flow path 192A and the second gas flow path 192B are formed between the dielectric member 13 and the cover 14.

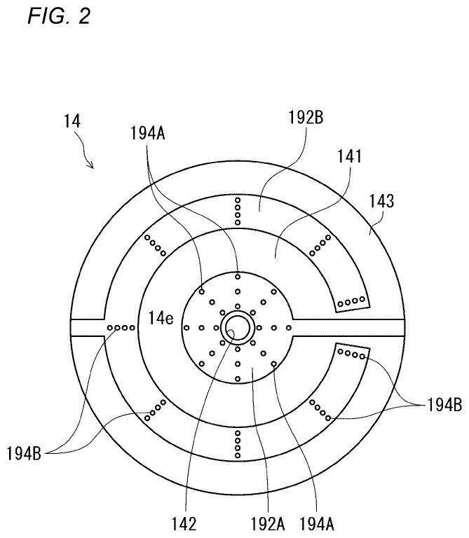

FIG. 2 is a schematic plan view of a cover according to one embodiment. The first gas flow path 192A is communicated with the exterior of the chamber 12 and with the first space S1 via the first gas release part (inner gas hole) 194A that passes through the cover 14 in the thickness direction. A plurality of the first gas release parts 194A are arranged at intervals in the circumferential direction at positions overlapping with the center area of the dielectric member 13 (see FIG. 2). A plurality of the first gas release parts 194A are arranged at intervals in the radial direction (left-right direction in FIG. 1). The first gas flow path 192A is formed between the cover 14 and the dielectric member 13. To the first gas flow path 192A, the raw material gas is supplied from the first gas storage unit.

The second gas flow path 192B is communicated with the exterior of the chamber 12 and with the first space S1 via the second gas release part (outer gas hole) 194B that passes through the cover 14 in the thickness direction. A plurality of the second gas release parts 194B are arranged at intervals in the circumferential direction at positions overlapping with the circumferential area of the dielectric member 13 (see FIG. 2). A plurality of the second gas release parts 194B are arranged at intervals in the radial direction (left-right direction in FIG. 1). The second gas flow path 192B is formed between the cover 14 and the dielectric member 13. To the second gas flow path 192B, the raw material gas is supplied from the second gas storage unit.

The cover 14 has a first raised portion 141 on the lower surface between the first gas release parts 194A and the second gas release parts 194B. The cover 14 has a second raised portion 142 provided inside the first gas release parts 194A. The cover 14 has a third raised portion 143 provided outside the second gas release parts 194B. The first raised portion 141, the second raised portion 142, and the third raised portion 143 are each formed in a ring shape, but are not limited thereto. The first gas flow path 192A and the second gas flow path 192B are separated from each other by the first, second and third raised portions 141, 142, and 143. This makes it easy to highly accurately control the flow rate of the raw material gas released into the chamber 12 from the first supply unit 19A and the second supply unit 19B.

The flow rates of the raw material gas released into the chamber 12 from the first supply unit 19A and the second supply unit 19B are controlled by the control unit 211. The control unit 211 adjusts each flow rate through controlling the first flow rate controller 193A and the second flow rate controller 193B. Specifically, when the distribution information outputted by the measurement unit is to request to modify the process conditions, the second setting value regarding the ratio between the flow rates of the gas supplied from the first supply unit 19A and the gas supplied from the second supply unit 19B is modified by the modification unit, and each of the flow rates is modified by the control unit 211 according to the modified second setting value.

The measurement unit 20 includes a first sensor 201A, a second sensor 201B, and a data processing unit 202 that processes and outputs measurement data. The operations of the data processing unit 202 may be executed by a central processing unit (CPU) included in the computer. The memory unit 212 may store a program to be executed by the data processing unit 202.

The first sensor 201A is disposed above the first dielectric window 15a provided at the end of the protruding portion, and measures light emission from the center area of the plasma. The second sensor 201B is disposed outside the second dielectric window 12c provided on the sidewall of the chamber, and measures light emission from the circumferential area of the plasma.

The first sensor 201A includes a convex lens (not shown) that collects the light emitted from the plasma within the chamber, and a light emission detector (not shown) that detects through the convex lens the light emitted from the plasma. The first sensor 201A may include a collimator lens, instead of the convex lens.

The second sensor 201B includes a convex lens 203B (not shown) that collects the light emitted from the plasma within the chamber, and a light emission detector 204B that detects through the convex lens 203B the light emitted from the plasma within the chamber. When measuring the plasma in the vicinity of the second dielectric window 12c, the convex lens 203B with a short focal length is used. For detecting light emission from plasma at a desired position in the circumferential area, mechanisms, such as the first driving unit and the second driving unit as described above, may be used.

Of a plurality of times of the unit processing repeated, in the unit processing (N) at an Nth time, where N is an integer, the first sensor 201A and the second sensor 201B of the measurement unit 20 measure, for example, the emission intensity of fluorine and the emission intensity of argon. The data processing unit 202 of the measurement unit 20 converts the data measured by the first sensor 201A and the second sensor 201B into, for example, an F/Ar ratio, and outputs it as the distribution information (N). When the modification unit 213 determines the distribution information (N) (F/Ar ratio) as satisfying a predetermined condition (when the distribution information indicating that the plasma distribution is not sufficiently uniform is outputted), the process conditions are modified in the unit processing (M) at an Mth time, where M is any integer equal to or greater than (N+1).

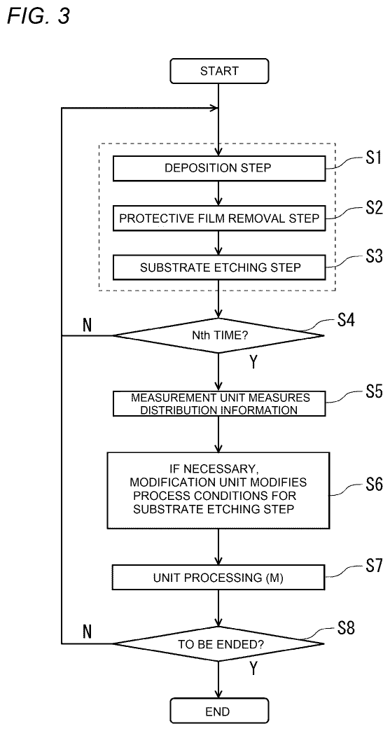

FIG. 3 is a flow diagram of a plasma processing method according to one embodiment. The flow of FIG. 3 corresponds to the flow of a Bosch process in which the unit processing includes a deposition step (S1) of depositing a protective film on the surface of a substrate, a protective film removal step (S2) of removing part of the protective film, to expose part of the substrate, and a substrate etching step (S3) of etching the exposed part of the substrate.

In the substrate etching step (S3), part of the substrate (silicon layer) is etched by plasma to form a recess in the substrate. On the substrate, a patterned mask is formed in advance. In the substrate etching step (S3), street regions of the substrate exposed from the mask are etched. In the deposition step (S1), a protective layer is formed on the inner side of the formed recess. In the protective layer removal step (S2), the protective layer present at the bottom of the recess is etched by plasma, whereas the protective film present on the sidewall of the recess remains, protecting the sidewall. By repeating such unit processing, the substrate is deeply etched.

The raw material gas for the plasma includes a fluorine source and argon. Argon contained in the raw material gas is introduced for easily grasping the state of the plasma. Argon may be introduced at such a concentration that does not significantly affect the process and allows the emission intensity to be confirmed. The argon concentration in the raw material gas may be, for example, 3 vol % to 5 vol %. As the fluorine source, CF₄, C₄F₈, CHF₃, CH₂F₂, NF₃, XeF₂, XeF₆, SF₆, etc. can be used. These fluorine sources may be used singly or in combination of two or more. In addition to Ar or in place of Ar, an inert gas, such as He, may be used, and an oxygen-containing gas, such as O2, CO, or CO₂, may be used.

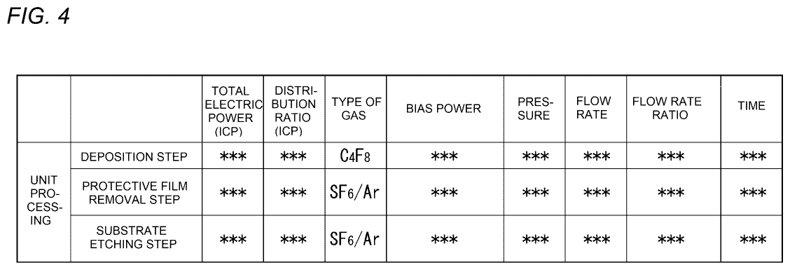

FIG. 4 conceptually shows an example of process conditions. The process conditions include the total electric power outputted from the high-frequency power source 181, the distribution ratio of electric power distributed between the first coil 184A and the second coil 184B by the distributor 183, the type of the raw material gas, the high-frequency power (bias power) applied to the placement unit 11, the pressure of gas in the chamber, the flow rate of the raw material gas, the ratio of the flow rates of the raw material gas supplied into chamber 12 from the first supply unit 19A and the second supply unit 19B, the time of each step, etc. Note that the process conditions for the protective film removal step (S2) and the substrate etching step (S3) may be the same, except for the bias power and the time.

In the deposition step, the processing is performed under the conditions in which, for example, while C₄F₈ is supplied as a raw material gas at a flow rate of 150 to 300 sccm and a flow rate ratio of 0.1 to 10, the pressure in the chamber is adjusted to 15 to 25 Pa, with the total electric power outputted from the high-frequency power source 181 set to 1500 to 5000 W, the distribution ratio set to 0.1 to 10, the bias power set to 0 to 50 W, and the processing time set to 2 to 10 seconds.

In the protective film removal step, the processing is performed under the conditions in which, for example, while a mixed gas of SF₆ and Ar is supplied as a raw material gas at a flow rate of 200 to 600 sccm and a flow rate ratio of 0.1 to 10, the pressure in the chamber is adjusted to 5 to 25 Pa, with the total electric power outputted from the high-frequency power source 181 set to 1500 to 5000 W, the distribution ratio set to 0.1 to 10, the bias power set to 80 to 800 W, and the processing time set to 1 to 5 seconds.

In the etching step, the processing is performed under the conditions in which, for example, while a mixed gas of SF₆ and Ar is supplied as a raw material gas at a flow rate of 200 to 600 sccm and a flow rate ratio of 0.1 to 10, the pressure in the chamber is adjusted to 5 to 25 Pa, with the total electric power outputted from the high-frequency power source 181 set to 1500 to 6000 W, the distribution ratio set to 0.1 to 10, the bias power set to 20 to 500 W, and the processing time set to 4 to 15 seconds.

In the plasma processing method, in the unit processing (N) at an Nth time, where Nis an integer, the distribution information (N) regarding the plasma distribution is measured by the measurement unit 20 (S4, S5). For example, the measurement unit 20 may measure the distribution information every time the unit processing is performed any number of times from 1 to 10.

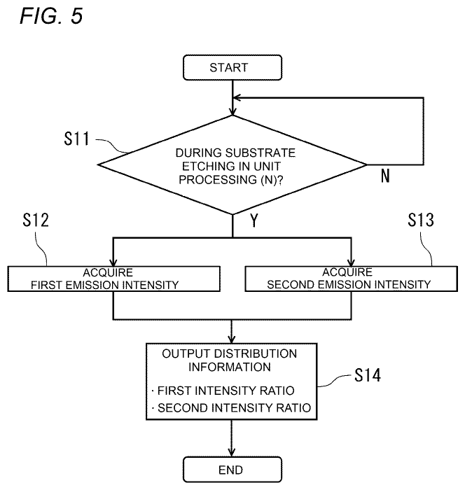

FIG. 5 is a flow diagram of the operation of the measurement unit according to one embodiment. For example, when the control unit 211 notifies the measurement unit 20 of the timing of the substrate etching step (S3) in the unit processing (N) at an Nth time, where N is an integer (Y in S11), the first sensor 201A and the second sensor 201B acquire the emission intensity of plasma (S12, S13). When the plasma raw material gas contains a fluorine source and argon, the emission intensity of fluorine and the emission intensity of argon may be measured. The data processing unit 202 of the measurement unit 20 converts the data measured by the first sensor 201A and the second sensor 201B into a first intensity ratio (F/Ar ratio) and a second intensity ratio (F/Ar ratio), respectively, and outputs them as the distribution information (N) (S14).

When the measurement unit 20 outputs the distribution information (N) (e.g., F/Ar ratio) indicating that the plasma distribution is not sufficiently uniform, the modification unit 213 modifies the process conditions (e.g., the first setting value or the second setting value) in the unit processing (M) at an M=(N+1)th time (S6).

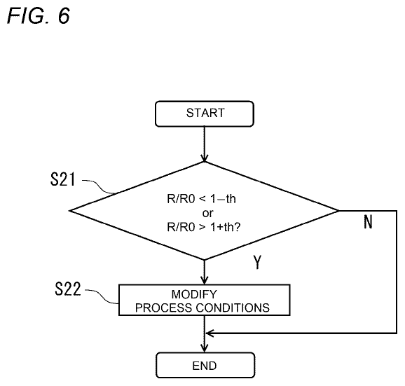

FIG. 6 is a flow diagram of the operation of the modification unit according to one embodiment. For example, the modification unit 213 compares the first intensity ratio with the second intensity ratio (S21). If the ratio (R/R0) between the ratio (R) of the first intensity ratio to the second intensity ratio and an ideal value (R0) is apart by a predetermined threshold value (th) or more (R/R0<1-th or R/R0>1+th), the modification unit 213 modifies the process conditions (for the substrate etching step, etc.) in the subsequent unit processing (M) (S22), so that the unit processing (M) is performed under the modified conditions (S7). Here, the ideal value (R0) is the ratio between the first intensity ratio and the second intensity ratio when the plasma distribution is uniform. When the unit processing is repeated a predetermined number of times (Y in S8), the flow of the plasma processing method ends (see FIG. 3).

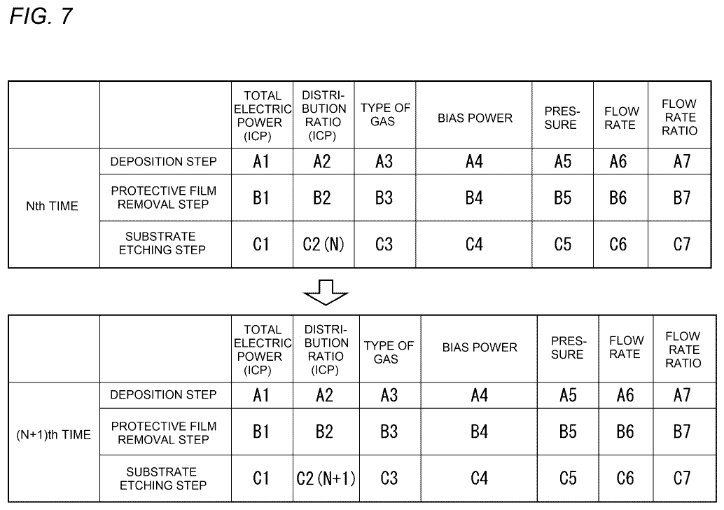

FIG. 7 is a conceptual diagram of a modification example of the process conditions. FIG. 7 shows an example in which, based on the distribution information (N), the distribution ratio in the substrate etching step (S3), which is the first setting value in the M=(N+1)th unit processing, is modified.

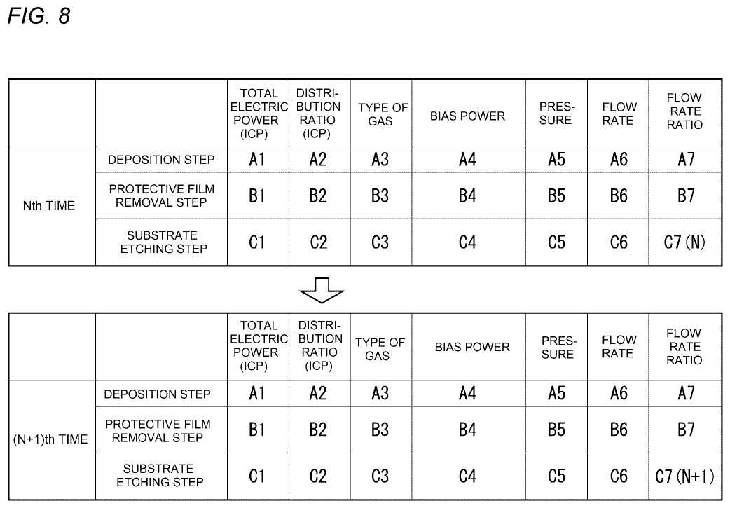

FIG. 8 is a conceptual diagram of another modification example of the process conditions. FIG. 8 shows an example in which, based on the distribution information (N), the ratio of the flow rates of the raw material gas supplied into the chamber 12 from the first supply unit 19A and the second supply unit 19B in the substrate etching step (S3), which is the second setting value in the M=(N+1)th unit processing, is modified.

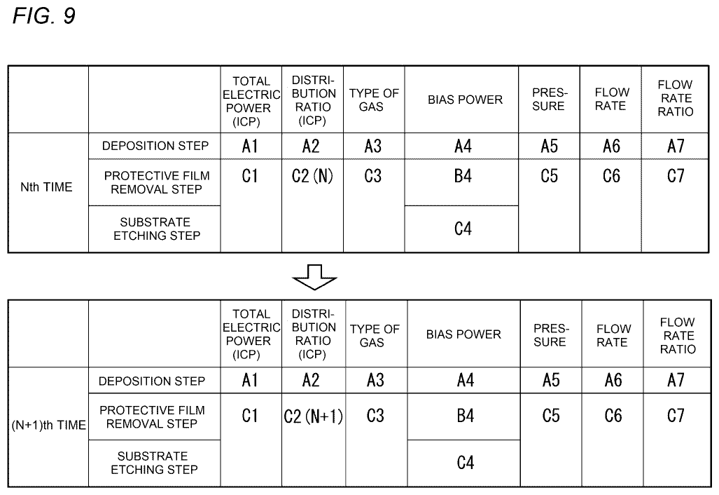

FIG. 9 is a conceptual diagram of yet another modification example of the process conditions. FIG. 9 shows an example in which, based on the distribution information (N), the distribution ratios in the protective film removal step (S2) and the substrate etching step (S3), which is the first setting value in the M=(N+1)th unit processing, are simultaneously modified.

### (Supplementary Notes)

The following techniques are disclosed by the foregoing description of embodiments.

### (Technique 1)

A plasma processing apparatus, comprising:
a chamber;
a placement unit which is disposed in the chamber and on which a substrate is to be placed;
a plasma generation unit configured to generate a plasma within the chamber;
a gas supply unit configured to supply a raw material gas of the plasma into the chamber;
a measurement unit configured to measure and output a distribution information regarding a plasma distribution in the chamber;
a control unit configured to control the plasma generation unit and the gas supply unit so as to repeat a unit processing on the substrate;
a memory unit configured to store process conditions including conditions for the unit processing; and
a modification unit configured to modify the process conditions, wherein
the measurement unit measures the distribution information (N) in the unit processing (N) at an Nth time, where N is an integer, and
when the distribution information (N) satisfies a predetermined condition, the modification unit modifies the process conditions in the unit processing (M) at an Mth time, where M is any integer equal to or greater than (N+1).

### (Technique 2)

The plasma processing apparatus according to technique 1, wherein
the unit processing includes
   a deposition step of depositing a protective film on a surface of the substrate,
   a protective film removal step of removing part of the protective film, to expose part of the substrate, and
   a substrate etching step of etching the exposed part of the substrate, and the modification unit modifies at least a condition of the substrate etching step in the unit processing (M), based on the distribution information (N).

### (Technique 3)

The plasma processing apparatus according to technique 2, wherein the modification unit further modifies a condition of the protective film removal step in the unit processing (M).

### (Technique 4)

The plasma processing apparatus according to any one of techniques 1 to 3, wherein
the measurement unit includes
   a first sensor configured to measure light emission from a center area of the plasma generated in the chamber, and
   a second sensor configured to measure light emission from a circumferential area of the plasma generated in the chamber,
   and outputs the distribution information, based on a first emission intensity measured by the first sensor and a second emission intensity measured by the second sensor.

### (Technique 5)

The plasma processing apparatus according to technique 4, wherein
the raw material gas contains a fluorine source and argon,
the measurement unit outputs, as the distribution information, a first intensity ratio and a second intensity ratio,
the first intensity ratio is a ratio of an emission intensity attributed to fluorine generated from the fluorine source to an emission intensity attributed to the argon, the emission intensities measured by the first sensor,
the second intensity ratio is a ratio of an emission intensity attributed to the fluorine to an emission intensity attributed to the argon, the emission intensities measured by the second sensor, and
the modification unit modifies the process conditions, based on the distribution information, and on an interdependency data acquired in advance between a ratio of an emission intensity attributed to fluorine to an emission intensity attributed to argon and an etching rate of the substrate.

### (Technique 6)

The plasma processing apparatus according to any one of techniques 1 to 5, wherein
the plasma generation unit includes
   a first coil for generating a plasma in a center area within the chamber,
   a second coil for generating a plasma in a circumferential area within the chamber, and
   a power supply unit configured to supply a high-frequency power to each of the first coil and the second coil,
the process conditions include a first setting value regarding an electric power supplied from the power supply unit to each of the first coil and the second coil, and
the modification unit modifies the first setting value in the Mth unit processing (M), based on the distribution information.

### (Technique 7)

The plasma processing apparatus according to technique 6, wherein
the power supply unit includes
   one high-frequency power source,
   a matcher connected to an output end of the high-frequency power source, and
   a distributor connected to the matcher on an opposite side to the high-frequency power source and configured to distribute a total electric power supplied from the high-frequency power source between the first coil and the second coil at a predetermined distribution ratio,
the control unit configured to control the distribution ratio of the distributor,
the first setting value includes the distribution ratio, and
the modification unit modifies the distribution ratio in the Mth unit processing (M), based on the distribution information.

### (Technique 8)

The plasma processing apparatus according to technique 7, wherein the modification unit modifies the distribution ratio in the Mth unit processing (M) based on the distribution information, without modifying the total electric power.

### (Technique 9)

The plasma processing apparatus according to any one of techniques 1 to 8, wherein
the gas supply unit includes
   a first supply unit configured to supply the raw material gas in a center area of the chamber, and
   a second supply unit configured to supply the raw material gas in a circumferential area of the chamber,
the process conditions include a second setting value regarding the raw material gas supplied into the chamber from each of the first supply unit and the second supply unit, and
the modification unit modifies the second setting value in the Mth unit processing (M), based on the distribution information.

### (Technique 10)

A plasma processing method in which a unit processing with respect to a substrate is repeated using a plasma generated by application of a high-frequency power to a raw material gas supplied from a gas supply unit, the method comprising:
a measurement step of measuring and outputting a distribution information regarding a plasma distribution in the unit processing (N) at an Nth time, where Nis an integer; and
a modification step of, when the distribution information measured in the measurement step satisfies a predetermined condition, modifying the process conditions in the unit processing (M) at an Mth time, where M is any integer equal to or greater than (N+1).

### (Technique 11)

The plasma processing method according to technique 10, wherein
the unit processing includes
   a deposition step of depositing a protective film on a surface of the substrate,
   a protective film removal step of removing part of the protective film, to expose part of the substrate, and
   a substrate etching step of etching the exposed part of the substrate, and
the modification step is a step of modifying at least a condition of the substrate etching step in the unit processing (M), based on the distribution information (N).

### (Technique 12)

The plasma processing method according to technique 11, wherein the modification step further modifies a condition of the protective film removal step in the unit processing (M).

### (Technique 13)

The plasma processing method according to any one of techniques 10 to 12, wherein
the measurement step includes
   a first measurement step of measuring light emission from a center area of the plasma generated in the chamber, with a first sensor,
   a second measurement step of measuring light emission from a circumferential area of the plasma generated in the chamber, with a second sensor, and
   a step of outputting the distribution information, based on a first emission intensity measured by the first sensor and a second emission intensity measured by the second sensor.

### (Technique 14)

The plasma processing method according to technique 13, wherein
the raw material gas contains a fluorine source and argon,
the measurement step outputs, as the distribution information, a first intensity ratio and a second intensity ratio,
the first intensity ratio is a ratio of an emission intensity attributed to fluorine generated from the fluorine source to an emission intensity attributed to the argon, the emission intensities measured by the first sensor,
the second intensity ratio is a ratio of an emission intensity attributed to the fluorine to an emission intensity attributed to the argon, the emission intensities measured by the second sensor, and
the modification step modifies the process conditions, based on the distribution information, and on an interdependency data acquired in advance between a ratio of an emission intensity attributed to fluorine to an emission intensity attributed to argon and an etching rate of the substrate.

### (Technique 15)

The plasma processing method according to any one of techniques 10 to 14, wherein
the plasma is generated by
   a first coil for generating a plasma in a center area within the chamber,
   a second coil for generating a plasma in a circumferential area within the chamber, and
   a plasma generation part including a power supply unit configured to supply a high-frequency power to each of the first coil and the second coil,
   the process conditions include a first setting value regarding an electric power supplied from the power supply unit to each of the first coil and the second coil, and
the modification step modifies the first setting value in the Mth unit processing (M), based on the distribution information.

### (Technique 16)

The plasma processing method according to technique 15, wherein
the power supply unit includes
   one high-frequency power source,
   a matcher connected to an output end of the high-frequency power source, and
   a distributor connected to the matcher on a side opposite to the high-frequency power source and configured to distribute a total electric power supplied from the high-frequency power source between the first coil and the second coil, at a predetermined distribution ratio,
the first setting value includes the distribution ratio, and
the modification step modifies the distribution ratio in the Mth unit processing (M), based on the distribution information.

### (Technique 17)

The plasma processing method according to technique 16, wherein the modification step modifies the distribution ratio in the Mth unit processing (M) based on the distribution information, without modifying the total electric power.

### (Technique 18)

The plasma processing method according to any one of techniques 10 to 17, wherein
the gas supply unit includes
   a first supply unit configured to supply the raw material gas into the chamber in a center area of the chamber, and
   a second supply unit configured to supply the raw material gas into the chamber in a circumferential area of the chamber,
the process conditions include a second setting value regarding the raw material gas supplied into the chamber from each of the first supply unit and the second supply unit, and
the modification step modifies the second setting value in the Mth unit processing (M), based on the distribution information.

The present disclosure is applicable to a plasma processing apparatus and a plasma processing method.

Although the present invention has been described in terms of the presently preferred embodiments, it is to be understood that such disclosure is not to be interpreted as limiting. Various alterations and modifications will no doubt become apparent to those skilled in the art to which the present invention pertains, after having read the above disclosure. Accordingly, it is intended that the appended claims be interpreted as covering all alterations and modifications as fall within the true spirit and scope of the invention.

### REFERENCE NUMERALS

10: plasma processing apparatus
11: placement unit
11a: placement surface
12: chamber
12a: opening
12b: exhaust port
12c: second dielectric window
13: dielectric member
13a: first through-hole
13b: recessed portion
14: cover
14a: second through-hole
141: first raised portion
142: second raised portion
143: third raised portion
15: protruding portion
15a: first dielectric window
18: plasma generation unit
181: high-frequency power source
182: matcher
183: distributor
183A: first distribution circuit
183B: second distribution circuit
184A: first coil
184B: second coil
19: gas supply unit
19A: first gas supply unit
192A: first gas flow path
193A: first flow controller
194A: first gas release part
19B: second gas supply unit
192B: second gas flow path
193B: second flow controller
194B: second gas release part
20: measurement unit
201A: first sensor
201B: second sensor
202: data processing unit
203B: convex lens
204B: light emission detector
21: Computer
211: control unit
212: memory unit
213: modification unit
S1: first space
S2: second space
F: frame
R: resin sheet
S: substrate

What is claimed is:

1. A plasma processing apparatus, comprising:
a chamber;
a placement unit which is disposed in the chamber and on which a substrate is to be placed;
a plasma generation unit configured to generate a plasma within the chamber;
a gas supply unit configured to supply a raw material gas of the plasma into the chamber;
a measurement unit configured to measure and output a distribution information regarding a plasma distribution in the chamber;
a control unit configured to control the plasma generation unit and the gas supply unit so as to repeat a unit processing on the substrate;
a memory unit configured to store process conditions including conditions for the unit processing; and
a modification unit configured to modify the process conditions, wherein
the measurement unit measures the distribution information (N) in the unit processing (N) at an Nth time, where N is an integer, and
when the distribution information (N) satisfies a predetermined condition, the modification unit modifies the process conditions in the unit processing (M) at an Mth time, where M is any integer equal to or greater than (N+1).

2. The plasma processing apparatus according to claim 1, wherein
the unit processing includes
a deposition step of depositing a protective film on a surface of the substrate,
a protective film removal step of removing part of the protective film, to expose part of the substrate, and
a substrate etching step of etching the exposed part of the substrate, and
the modification unit modifies at least a condition of the substrate etching step in the unit processing (M), based on the distribution information (N).

3. The plasma processing apparatus according to claim 2, wherein the modification unit further modifies a condition of the protective film removal step in the unit processing (M).

4. The plasma processing apparatus according to claim 1, wherein
the measurement unit includes
a first sensor configured to measure light emission from a center area of the plasma generated in the chamber, and
a second sensor configured to measure light emission from a circumferential area of the plasma generated in the chamber,
and outputs the distribution information, based on a first emission intensity measured by the first sensor and a second emission intensity measured by the second sensor.

5. The plasma processing apparatus according to claim 4, wherein
the raw material gas contains a fluorine source and argon,
the measurement unit outputs, as the distribution information, a first intensity ratio and a second intensity ratio,
the first intensity ratio is a ratio of an emission intensity attributed to fluorine generated from the fluorine source to an emission intensity attributed to the argon, the emission intensities measured by the first sensor,
the second intensity ratio is a ratio of an emission intensity attributed to the fluorine to an emission intensity attributed to the argon, the emission intensities measured by the second sensor, and
the modification unit modifies the process conditions, based on the distribution information, and on an interdependency data acquired in advance between a ratio of an emission intensity attributed to fluorine to an emission intensity attributed to argon and an etching rate of the substrate.

6. The plasma processing apparatus according to claim 1, wherein
the plasma generation unit includes
a first coil for generating a plasma in a center area within the chamber,
a second coil for generating a plasma in a circumferential area within the chamber, and
a power supply unit configured to supply a high-frequency power to each of the first coil and the second coil,
the process conditions include a first setting value regarding an electric power supplied from the power supply unit to each of the first coil and the second coil, and
the modification unit modifies the first setting value in the Mth unit processing (M), based on the distribution information.

7. The plasma processing apparatus according to claim 6, wherein
the power supply unit includes
one high-frequency power source,
a matcher connected to an output end of the high-frequency power source, and
a distributor connected to the matcher on an opposite side to the high-frequency power source and configured to distribute a total electric power supplied from the high-frequency power source to the first coil and the second coil at a predetermined distribution ratio,
the control unit configured to control the distribution ratio of the distributor,
the first setting value includes the distribution ratio, and
the modification unit modifies the distribution ratio in the Mth unit processing (M), based on the distribution information.

8. The plasma processing apparatus according to claim 7, wherein the modification unit modifies the distribution ratio in the Mth unit processing (M) based on the distribution information, without modifying the total electric power.

9. The plasma processing apparatus according to claim 1, wherein
the gas supply unit includes
a first supply unit configured to supply the raw material gas in a center area of the chamber, and
a second supply unit configured to supply the raw material gas in a circumferential area of the chamber,
the process conditions include a second setting value regarding the raw material gas supplied into the chamber from each of the first supply unit and the second supply unit, and
the modification unit modifies the second setting value in the Mth unit processing (M), based on the distribution information.

10. A plasma processing method in which a unit processing with respect to a substrate is repeated using a plasma generated by application of a high-frequency power to a raw material gas supplied from a gas supply unit, the method comprising:
a measurement step of measuring and outputting a distribution information regarding a plasma distribution in the unit processing (N) at an Nth time, where N is an integer; and
a modification step of, when the distribution information measured in the measurement step satisfies a predetermined condition, modifying the process conditions in the unit processing (M) at an Mth time, where M is any integer equal to or greater than (N+1).

11. The plasma processing method according to claim 10, wherein
the unit processing includes
a deposition step of depositing a protective film on a surface of the substrate,
a protective film removal step of removing part of the protective film, to expose part of the substrate, and
a substrate etching step of etching the exposed part of the substrate, and
the modification step is a step of modifying at least a condition of the substrate etching step in the unit processing (M), based on the distribution information (N).

12. The plasma processing method according to claim 11, wherein the modification step further modifies a condition of the protective film removal step in the unit processing (M).

13. The plasma processing method according to claim 10, wherein
the measurement step includes
a first measurement step of measuring light emission from a center area of the plasma generated in the chamber, with a first sensor,
a second measurement step of measuring light emission from a circumferential area of the plasma generated in the chamber, with a second sensor, and
a step of outputting the distribution information, based on a first emission intensity measured by the first sensor and a second emission intensity measured by the second sensor.

14. The plasma processing method according to claim 13, wherein
the raw material gas contains a fluorine source and argon,
the measurement step outputs, as the distribution information, a first intensity ratio and a second intensity ratio,
the first intensity ratio is a ratio of an emission intensity attributed to fluorine generated from the fluorine source to an emission intensity attributed to the argon, the emission intensities measured by the first sensor,
the second intensity ratio is a ratio of an emission intensity attributed to the fluorine to an emission intensity attributed to the argon, the emission intensities measured by the second sensor, and
the modification step modifies the process conditions, based on the distribution information, and on an interdependency data acquired in advance between a ratio of an emission intensity attributed to fluorine to an emission intensity attributed to argon and an etching rate of the substrate.

15. The plasma processing method according to claim 10, wherein
the plasma is generated by
a first coil for generating a plasma in a center area within the chamber,
a second coil for generating a plasma in a circumferential area within the chamber, and
a plasma generation part including a power supply unit configured to supply a high-frequency power to each of the first coil and the second coil,
the process conditions include a first setting value regarding an electric power supplied from the power supply unit to each of the first coil and the second coil, and
the modification step modifies the first setting value in the Mth unit processing (M), based on the distribution information.

16. The plasma processing method according to claim 15, wherein
the power supply unit includes
one high-frequency power source,
a matcher connected to an output end of the high-frequency power source, and
a distributor connected to the matcher on a side opposite to the high-frequency power source and configured to distribute a total electric power supplied from the high-frequency power source between the first coil and the second coil at a predetermined distribution ratio,
the first setting value includes the distribution ratio, and
the modification step modifies the distribution ratio in the Mth unit processing (M), based on the distribution information.

17. The plasma processing method according to claim 16, wherein the modification step modifies the distribution ratio in the Mth unit processing (M) based on the distribution information, without modifying the total electric power.

18. The plasma processing method according to claim 10, wherein
the gas supply unit includes
a first supply unit configured to supply the raw material gas into the chamber in a center area of the chamber, and
a second supply unit configured to supply the raw material gas into the chamber in a circumferential area of the chamber,
the process conditions include a second setting value regarding the raw material gas supplied into the chamber from each of the first supply unit and the second supply unit, and
the modification step modifies the second setting value in the Mth unit processing (M), based on the distribution information.
